(19) United States
(12) Patent Application Publication
(10) Pub. No.: US 2018/0046084 A1
(43) Pub. Date: Feb. 15, 2018

(54) PHOTORESIST PRE-BAKING METHOD, PHOTORESIST PRE-BAKING DEVICE AND LITHOGRAPHIC APPARATUS

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventor: Yanchun LU, Beijing (CN)

(21) Appl. No.: 15/658,450

(22) Filed: Jul. 25, 2017

(30) Foreign Application Priority Data
Aug. 12, 2016 (CN) 201610666188.2

(51) Int. Cl. G03F 7/38

(52) U.S. Cl. CPC G03F 7/38

(57) ABSTRACT

A photoresist pre-baking method, a photoresist pre-baking device and a lithographic apparatus are disclosed. The device includes a heating plate and a temperature controller. The heating plate includes a plurality of heating units, and the heating plate is configured to heat a substrate to be baked through the plurality of heating units, and the temperature controller is electrically connected with each of the heating units, and configured to adjust a heating parameter of each of the heating units of the heating plate, the heating parameter including at least one of a heating temperature and a heating duration.

### CROSS-REFERENCE TO RELATED APPLICATIONS

The present application claims priority to Chinese Patent Application No. 201610666188.2, filed Aug. 12, 2016, and the entire contents of which are incorporated herein by reference.

### TECHNICAL FIELD

The present disclosure relates to the field of display technology, and more particularly to a photoresist pre-baking method, a photoresist pre-baking device and a lithographic apparatus.

### BACKGROUND

In a process of preparing a thin film transistor (TFT) array substrate, coating with a photoresist, pre-baking, exposing, developing, post-baking and other lithography processes are needed. Among them, the pre-baking process is mainly used to preheat the photoresist, and remove moisture in the photoresist to increase the adhesion between the photoresist and a substrate.

In the related art, a photoresist pre-baking device employed in a lithographic process is generally a heating plate, and the heating plate is capable of carrying and heating the substrate to be baked.

However, the photoresist pre-baking device in the related art can only uniformly heat the substrate to be baked, and the use of the photoresist pre-baking device is less flexible.

### SUMMARY

In a first aspect, a photoresist pre-baking device is provided, which includes a heating plate and a temperature controller, wherein the heating plate comprises a plurality of heating units, and the heating plate is configured to heat a substrate to be baked through the plurality of heating units, and the temperature controller is electrically connected with each of the heating units, and configured to adjust a heating parameter of each of the heating units of the heating plate, the heating parameter comprising at least one of a heating temperature and a heating duration.

In one embodiment, the photoresist pre-baking device further includes a detector which is electrically connected with the temperature controller, and is configured to detect a thickness of a photoresist in each baking region of the substrate to be baked after a lithographic process and send the detected thickness of the photoresist in each baking region to the temperature controller, and the temperature controller is further configured to adjust a heating parameter of each of the heating units of the heating plate according to the thickness of the photoresist in each baking region.

In one embodiment, the photoresist pre-baking device further includes a processor which is electrically connected with the detector and the temperature controller, respectively, the detector is further configured to send the detected thickness of the photoresist in each baking region to the processor, the processor is configured to determine a target heating parameter of each baking region according to the thickness of the photoresist in each baking region, and send the target heating parameter of each baking region to the temperature controller, and the temperature controller is further configured to adjust the heating parameter of each of the heating units of the heating plate according to the target heating parameter of each baking region.

In one embodiment, each of the heating units is configured to heat a respective baking region of the substrate to be baked, and the temperature controller is further configured to set the heating parameter of each of the heating units as the target heating parameter of a baking region corresponding to each of the heating units.

In one embodiment, the baking region of the substrate to be baked comprises a display region, a first driving region around the display region for disposing a source driving circuit and a second driving region around the display region for disposing a gate driving circuit, and the temperature controller is further configured to adjust the heating parameter of each of the heating units of the heating plate, such that a heating temperature of a first heating unit is higher than a heating temperature of a second heating unit and/or a heating duration of the first heating unit is greater than a heating duration of the second heating unit, wherein the first heating unit is a heating unit for heating the second driving region, and the second heating unit is a heating unit for heating the display region and the first driving region.

In one embodiment, the heating plate is formed by splicing the plurality of heating units.

Alternatively, the heating plate further comprises a base substrate, and the plurality of heating units are formed on the base substrate.

In a second aspect, a photoresist pre-baking method of using the photoresist pre-baking device described as above, including:

adjusting the heating parameter of each of the heating units of the heating plate by using the temperature controller, the heating parameter including at least one of a heating temperature and a heating duration; and

heating the substrate to be baked by using each of the heating units of the heating plate.

In one embodiment, after the step of heating the substrate to be baked by using each of the heating units of the heating plate, the method further includes:

detecting a thickness of a photoresist in each baking region of the substrate to be baked after a lithographic process, and the step of adjusting the heating parameter of each of the heating units of the heating plate by using the temperature controller includes:

adjusting the heating parameter of each of the heating units of the heating plate according to the thickness of the photoresist in each baking region.

In one embodiment, after the step of detecting the thickness of the photoresist in each baking region of the substrate to be baked after the lithographic process, the method further includes:

determining a target heating parameter of each baking region according to the thickness of the photoresist in each baking region,

the step of adjusting the heating parameter of each of the heating units of the heating plate by using the temperature controller includes:

adjusting the heating parameter of each of the heating units of the heating plate according to the target heating parameter of each baking region.

In one embodiment, each of the heating units is configured to heat a respective baking region of the substrate to be baked, and the step of adjusting the heating parameter of each of the heating units of the heating plate according to the target heating parameter of each baking region includes:

setting the heating parameter of each of the heating units as the target heating parameter of a baking region corresponding to each of the heating units.

In one embodiment, the baking region of the substrate to be baked comprises a display region, a first driving region around the display region for disposing a source driving circuit and a second driving region around the display region for disposing a gate driving circuit,

the step of adjusting the heating parameter of each of the heating units of the heating plate by using the temperature controller includes:

adjusting the heating parameter of each of the heating units of the heating plate, such that a heating temperature of a first heating unit is higher than a heating temperature of a second heating unit and/or a heating duration of the first heating unit is greater than a heating duration of the second heating unit,

wherein the first heating unit is a heating unit for heating the second driving region, and the second heating unit is a heating unit for heating the display region and the first driving region.

In a third aspect, a lithographic apparatus is provided, which includes the photoresist pre-baking device described as above.

### BRIEF DESCRIPTION OF THE DRAWINGS

In order to more clearly illustrate the technical solution in the embodiments of the present disclosure, the drawings, which are intended to be used in the description of the embodiments, will be briefly described below. It will be apparent that the drawings in the following description are merely examples of the present disclosure, and other drawings may be obtained by those skilled in the art without making creative work.

FIG. 1 is a structural schematic diagram of a photoresist pre-baking device according to an embodiment of the present disclosure;

FIG. 2 is a structural schematic diagram of another photoresist pre-baking device according to an embodiment of the present disclosure;

FIG. 3 is a flow chart of a lithographic process according to an embodiment of the present disclosure;

FIG. 4 is a schematic diagram of a substrate to be baked according to an embodiment of the present disclosure;

FIG. 5 is a structural schematic diagram of another photoresist pre-baking device according to an embodiment of the present disclosure;

FIG. 6 is a schematic diagram of a heating plate according to an embodiment of the present disclosure;

FIG. 7 is a flow chart of a photoresist pre-baking method according to an embodiment of the present disclosure; and

FIG. 8 is a flow chart of another photoresist pre-baking method according to an embodiment of the present disclosure.

### DETAILED DESCRIPTION

In order to that the objects, technical solutions and advantages of the present disclosure become more clear, the implementations of the present disclosure will be described in further detail below in conjunction with the accompanying drawings.

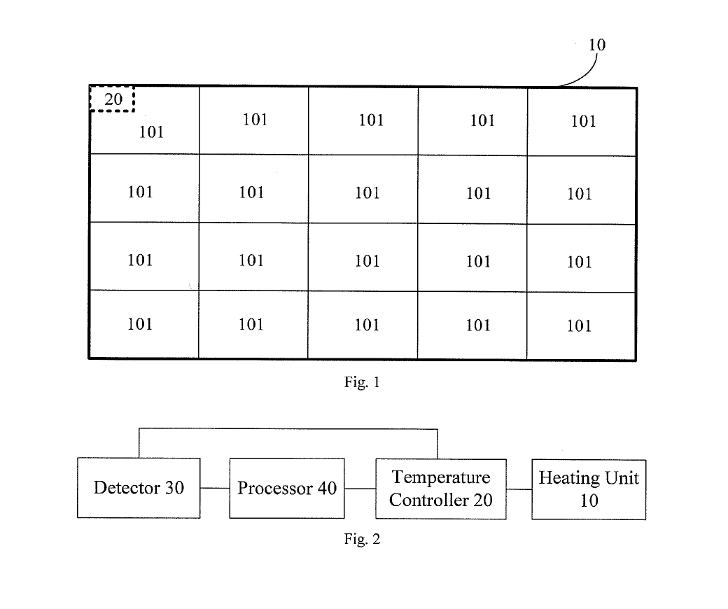

FIG. 1 is a structural schematic diagram of a photoresist pre-baking device according to an embodiment of the present disclosure. As shown in FIG. 1, the device includes a heating plate 10 and a temperature controller 20.

The heating plate 10 includes a plurality of heating units 101, and the heating plate 10 is configured to heat a substrate to be baked (not shown in FIG. 1) through the plurality of heating units 101.

The temperature controller 20 is electrically connected with each of the heating units 101, and is configured to adjust a heating parameter of each of the heating units 101 of the heating plate 10. The heating parameter may include at least one of a heating temperature and a heating duration.

In summary, the present disclosure provides a photoresist pre-baking device including a heating plate and a temperature controller. Since the temperature controller may adjust a heating parameter of each heating unit of the heating plate, the photoresist pre-baking device can provide different heating temperatures and heating durations for different baking regions of the substrate to be baked, thus flexibility in the use of the photoresist pre-baking device is improved.

FIG. 2 is a structural schematic diagram of a photoresist pre-baking device according to another embodiment of the present disclosure. As shown in FIG. 2, the device may further include a detector 30.

The detector 30 is electrically connected with the temperature controller 20, and is configured to detect a thickness of a photoresist in each baking region of the substrate to be baked after a lithographic process and send the detected thickness of the photoresist in each baking region to the temperature controller 20.

The temperature controller 20 is further configured to adjust a heating parameter of each heating unit of the heating plate according to the thickness of the photoresist in each baking region.

In particular, the temperature controller 20 may adjust the heating parameter of each heating unit 101 of the heating plate 10, such that a heating temperature of a first heating unit is higher than a heating temperature of a second heating unit and/or a heating duration of the first heating unit is greater than a heating duration of the second heating unit. The first heating unit is a heating unit for heating the second driving region, and the second heating unit is a heating unit for heating the display region and the first driving region.

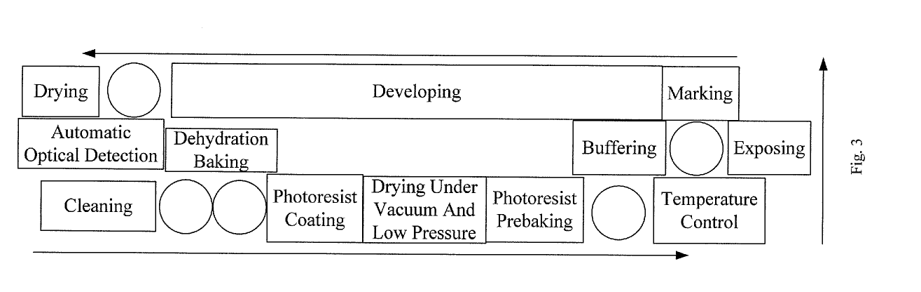

FIG. 3 is a flow chart of a lithographic process according to an embodiment of the present disclosure. As shown in FIG. 3, the lithographic process may include a plurality of processes such as cleaning, coating with a photoresist, pre-baking the photoresist, exposing, developing, drying and the like. The specific procedure of the lithographic process may be found in the related art, and will not be repeated in the embodiment of the present disclosure. The fluctuation of the process parameters in each process may affect the thickness of the photoresist in each region of the substrate in the lithographic process, thus, in an embodiment of the present disclosure, the substrate to be baked, which has been subjected to the lithographic process, can be sampled to be detected. For example, a thickness of a photoresist in a TFT channel of different regions of the substrate to be baked may be detected, and the heating parameter of each heating unit is adjusted in real time according to the detected thickness of the photoresist in each baking region, thereby effectively reducing the impact of the process fluctuation in the lithographic process on the thickness of the photoresist in various regions of the substrate to be baked.

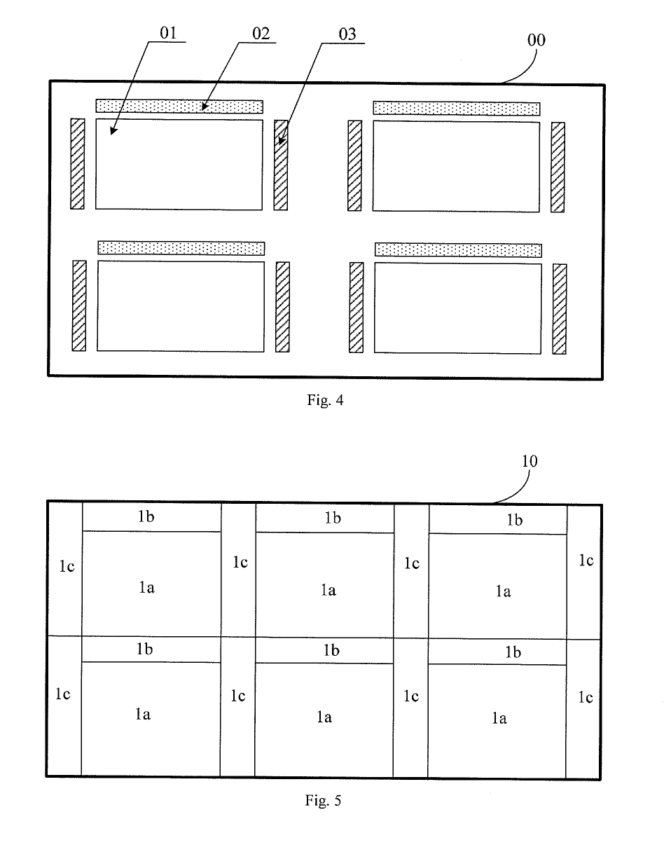

Referring to FIG. 4, the baking region of the substrate 00 to be baked may include a display region 01, a first driving region 02 around the display region 01 for disposing a source driving circuit, and a second driving region 03 around the display region 01 for disposing a gate driving circuit (GOA). Since densities of patterns in different baking regions are different from each other, for example, the number of TFTs that need to be formed in the second driving region 03 is larger, the density of the patterns in the second driving region 03 is larger, thus in the subsequent developing process, compared with the display region 01 and the first driving region 02, the amount of developing solution consumed in the second driving region 03 in a unit time is relatively small, and thus the concentration of the developing solution in the second driving region 03 during the developing process is higher, and the developing rate is quicker. In this case, after the lithographic process, the photoresist in the TFT channels of the second driving region 03 is thinner or depleted, such that an active layer in the TFT channel is etched to be penetrated through and an open circuit (also known as channel open) in an etching process appears. However, as for the display region 01, since the developing rate is slower, the thickness of the photoresist in the TFT channels of the display region 01 may be thicker after the lithographic process, such that metals of the source/drain channel of the TFT in this region may be bridged (also known as channel bridge) after the lithographic process.

In an embodiment of the present disclosure, the temperature controller may, according to data detected by the detector, make a heating temperature of a heating unit corresponding to a region in which the photoresist has a smaller thickness to be higher, and make a heating duration to be longer, such that a hardness of the photoresist in the region is increased, thereby reducing the consumption of the photoresist in the region during the subsequent lithographic process. As for a heating unit corresponding to a region in which the photoresist has a greater thickness, a heating temperature of the heating unit may be decreased, and a heating duration is reduced, such that a hardness of the photoresist in the region is reduced, thereby increasing the consumption of the photoresist in the region during the subsequent lithographic process. Therefore, after the substrate is subjected to the subsequent lithographic process, the thickness of the photoresist in each region is more uniform, and the probability of a bad GOA region is reduced.

In one embodiment, as shown in FIG. 2, the device may further include a processor 40, and the processor 40 is electrically connected with the detector 30 and the temperature controller 20, respectively.

The detector 30 is further configured to send the detected thickness of the photoresist in each baking region to the processor.

The processor 40 is configured to determine a target heating parameter of each baking region according to the thickness of the photoresist in each baking region, and send the target heating parameter of each baking region to the temperature controller.

In an embodiment of the present disclosure, the thickness of the photoresist detected by the detector may be a thickness of a photoresist in a TFT channel. The processor may store a correspondence between the thickness of the photoresist and the heating parameter. When the processor receives the thickness of the photoresist in each baking region sent from the detector, the processor may determine a target heating parameter of each baking region according to the pre-stored correspondence. As an example, assuming that the correspondence between the thickness of the photoresist and the heating parameter stored in the processor is shown in table 1, the target heating parameter of the baking region in which the thickness of the photoresist in the TFT channel is 0.1 μm may be as follows: the heating temperature is 185° C., and the heating duration is 65 s. If the detector detects that the thickness of the photoresist in the TFT channels of the display region 01 and the first driving region 02 is 0.3 μm, the thickness of the photoresist in the TFT channels of the second driving region 03 is 0.1 μm. Thus the processor may determine that the target heating parameter of the display region 01 and the first driving region 02 is as follows: the heating temperature is 180° C., and the heating duration is 60 s; and the target heating parameter of the second driving region 03 is as follows: the heating temperature is 185° C., and the heating duration is 65 s.

TABLE 1

| Thickness of | Heating Parameter | |
|---|---|---|
| Photoresist (μm) | Heating Temperature(° C.) | Heating Duration (s) |
| 0.1 | 185 | 65 |
| 0.3 | 180 | 60 |
| 0.5 | 175 | 55 |

The temperature controller 20 is further configured to adjust the heating parameter of each of the heating units of the heating plate according to the target heating parameter of each baking region.

Here, each of the heating units is configured to heat a respective baking region of the substrate to be baked, and the temperature controller 20 is particularly configured to set the heating parameter of each of the heating units as the target heating parameter of a baking region corresponding to each of the heating units.

FIG. 5 is a structural schematic diagram of another photoresist pre-baking device according to an embodiment of the present disclosure. As shown in FIG. 5, assuming that a heating unit 1a of the heating plate 10 is used to heat the display region 01, a heating unit 1b is used to heat the first driving region 02, and a heating unit 1c is used to heat the second driving region 03, such that the temperature controller 20 may set the heating temperature for the heating unit 1a and the heating unit 1b as 180° C., and set the heating duration as 60 s; and set the heating temperature for the heating unit 1c as 185° C., and set the heating duration as 65 s. Thus the distinct heating of the display region, the first driving region and the second driving region of the substrate to be baked is achieved. After the heating is performed, since the heating temperature for heating the heating unit 1c of the second driving region 03 is higher, and the heating duration is longer, compared with the display region 01 and the first driving region 02, the photoresist in the second driving region 03 has a greater hardness after the pre-baking process, thus it is possible to reduce the depletion of the photoresist in the region during the subsequent exposing and developing processes to ensure the uniformity of the thickness of the photoresist in various regions of the substrate after the lithographic process.

In an embodiment of the present disclosure, the heating unit of the heating plate may be a resistive heating unit. For example, an electric heating wire may be provided in the heating unit, and the heating unit may generate heat when the heating wire is energized.

It is to be noted that, in the practical application, each heating unit of the heating plate may also be of any type other than the resistive type, and the embodiment of the present disclosure is not limited thereto.

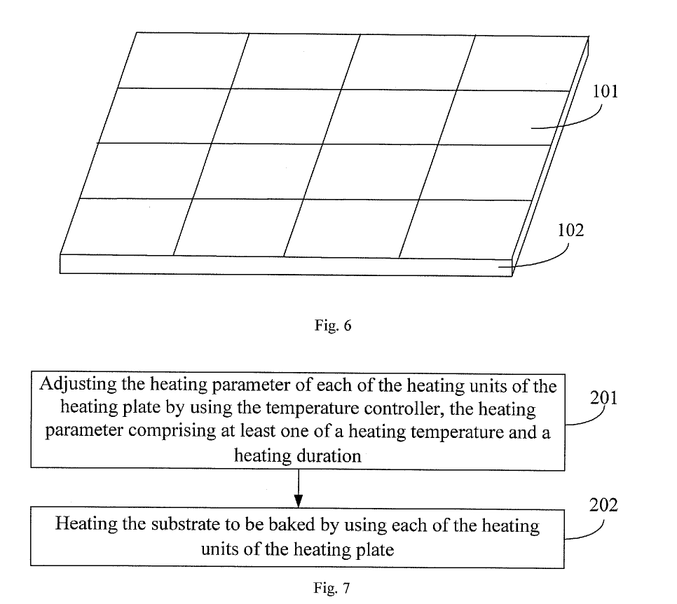

In an embodiment of the present disclosure, on the one hand, as shown in FIG. 1, the heating plate 10 may be formed by splicing a plurality of heating units 101. On the other hand, referring to FIG. 6, the heating plate may further include a base substrate 102, and the plurality of heating units 101 may be formed on the base substrate 102. There is no gap or a small gap between two adjacent heating units.

In summary, the present disclosure provides a photoresist pre-baking device, and the photoresist pre-baking device includes a heating plate and a temperature controller. Since the temperature controller can adjust the heating parameter of each heating unit of the heating plate such that the photoresist pre-baking device can provide different heating temperatures and heating durations for different baking regions of the substrate to be baked, the flexibility in the use of the photoresist pre-baking device is improved. Further, in addition to the developing process, the photoresist coating and exposing processes in the lithographic process may also affect the thickness of the photoresist in various regions of the substrate, such that the thicknesses of various regions of the substrate after the lithographic process are not uniform. However, in the photoresist pre-baking device provided by the embodiment of the present disclosure, since the heating parameter of each heating unit may be adjusted in real time according to the thickness of the photoresist on the substrate which has been subjected to the lithographic process, it is possible to effectively avoid the problem that the thickness of the photoresist is not uniform due to the process fluctuation in each lithographic process.

FIG. 7 is a flow chart of a photoresist pre-baking method according to an embodiment of the present disclosure. The method may be applied to the photoresist pre-baking device shown in any one of FIGS. 1, 2 and 5. As shown in FIG. 7, the method includes the following steps.

At step 201, the heating parameter of each of the heating units of the heating plate is adjusted by using the temperature controller, and the heating parameter includes at least one of a heating temperature and a heating duration.

At step 202, the substrate to be baked is heated by using each of the heating units of the heating plate.

In summary, the present disclosure provides a photoresist pre-baking method, and the method can adjust a heating parameter of each heating unit of the heating plate by using the temperature controller, such that the photoresist pre-baking device can provide different heating temperatures and heating durations for different baking regions of the substrate to be baked, thus flexibility in the use of the photoresist pre-baking process is improved.

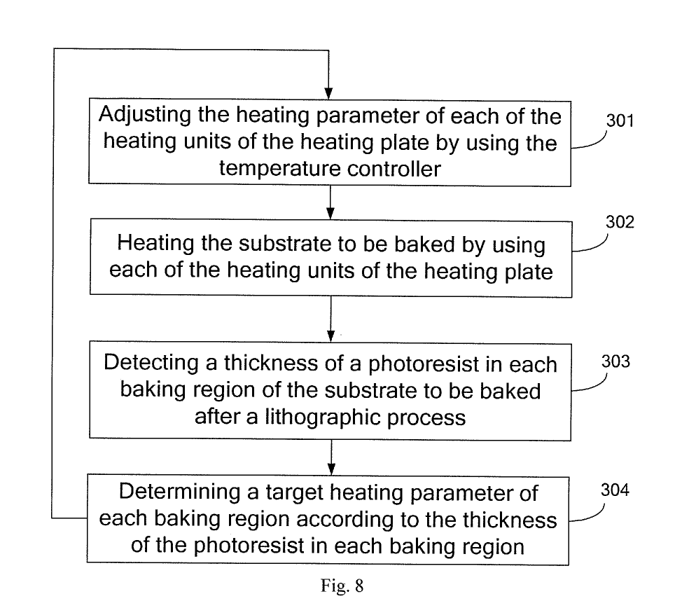

FIG. 8 is a flow chart of another photoresist pre-baking method according to an embodiment of the present disclosure. As shown in FIG. 8, the method includes the following steps.

At step 301, the heating parameter of each heating unit of the heating plate is adjusted by using the temperature controller.

The heating parameter includes at least one of a heating temperature and a heating duration. Referring to FIG. 4, the baking region of the substrate 00 to be baked includes a display region 01, a first driving region 02 around the display region 01 for disposing the source driving circuit, and a second driving region 03 around the display region 01 for disposing the gate driving circuit.

Thus the temperature controller may adjust the heating parameter of each heating unit of the heating plate, such that the heating temperature of the first heating unit is higher than the heating temperature of the second heating unit and/or the heating duration of the first heating unit is greater than the heating duration of the second heating unit.

Here, the first heating unit is a heating unit for heating the second driving region 03, and the second heating unit is a heating unit for heating the display region 01 and the first driving region 02.

At step 302, the substrate to be baked is heated by using each heating unit of the heating plate.

At step 303, the thickness of the photoresist in each baking region of the substrate to be baked is detected after the lithographic process.

At step 304, the target heating parameter of each baking region is determined according to the thickness of the photoresist in each baking region. The step 301 is performed.

In the embodiment of the present disclosure, when performing the lithographic process, the substrate to be baked, which has been subjected to the lithographic process, can be sampled periodically to be detected, and the target heating parameter of each baking region is determined according to the thickness of the photoresist in each baking region of the substrate. Thereafter, the step 301 may be performed again, such that the temperature controller can adjust the heating parameter of each heating unit of the heating plate according to the target heating parameter of each baking region. In particular, since each heating unit is used to heat a respective baking region of the substrate to be baked, the temperature controller can set the heating parameter of each heating unit as the target heating parameter of the baking region corresponding to each heating unit.

In summary, the present disclosure provides a photoresist pre-baking method, and the method can adjust the heating parameter of each heating unit of the heating plate by using the temperature controller, such that the photoresist pre-baking device can provide different heating temperatures and heating durations for different baking regions of the substrate to be baked, thus flexibility in the use of the photoresist pre-baking process is improved. Further, since the temperature controller can also adjust the heating parameter of each heating unit in real time according to the thickness of the photoresist on the substrate which has been subjected to the lithographic process, it is possible to effectively avoid the problem that the thickness of the photoresist is not uniform due to the process fluctuation in each lithographic process.

An embodiment of the present disclosure provides a lithographic apparatus, which may include the photoresist pre-baking device as shown in FIG. 1, 2 or 5.

It will be apparent to those skilled in the art that, for convenience and simplicity of the description, the specific process of the method described as above can refer to the corresponding process in the apparatus embodiment described as above and will not be described here.

The foregoing are merely specific embodiments of the present disclosure and are not intended to limit the present disclosure. Any modifications, equivalent substitutions, improvements, etc., which are within the spirit and principles of the present disclosure, are to be included within the scope of the present disclosure.

What is claimed is:

1. A photoresist pre-baking device, comprising:
a heating plate and a temperature controller,
wherein the heating plate comprises a plurality of heating units, and the heating plate is configured to heat a substrate to be baked through the plurality of heating units, and
the temperature controller is electrically connected with each of the heating units, and is configured to adjust a heating parameter of each of the heating units of the heating plate, the heating parameter comprises at least one of a heating temperature and a heating duration.

2. The photoresist pre-baking device of claim 1 further comprising a detector which is electrically connected with the temperature controller, and is configured to detect a thickness of a photoresist in each baking region of the substrate to be baked after a lithographic process and send the detected thickness of the photoresist in each baking region to the temperature controller, wherein the temperature controller is further configured to adjust a heating parameter of each of the heating units of the heating plate according to the thickness of the photoresist in each baking region.

3. The photoresist pre-baking device of claim 2 further comprising a processor which is electrically connected with the detector and the temperature controller, respectively, wherein
the detector is further configured to send the detected thickness of the photoresist in each baking region to the processor,
the processor is configured to determine a target heating parameter of each baking region according to the thickness of the photoresist in each baking region, and send the target heating parameter of each baking region to the temperature controller, and
the temperature controller is further configured to adjust the heating parameter of each of the heating units of the heating plate according to the target heating parameter of each baking region.

4. The photoresist pre-baking device of claim 3, wherein each of the heating units is configured to heat a respective baking region of the substrate to be baked, and the temperature controller is further configured to set the heating parameter of each of the heating units as the target heating parameter of a baking region corresponding to each of the heating units.

5. The photoresist pre-baking device of claim 1, wherein
the baking region of the substrate to be baked comprises a display region, a first driving region around the display region for disposing a source driving circuit and a second driving region around the display region for disposing a gate driving circuit, and
the temperature controller is further configured to adjust the heating parameter of each of the heating units of the heating plate, such that a heating temperature of a first heating unit is higher than a heating temperature of a second heating unit and/or a heating duration of the first heating unit is greater than a heating duration of the second heating unit, and
the first heating unit is a heating unit for heating the second driving region, and the second heating unit is a heating unit for heating the display region and the first driving region.

6. The photoresist pre-baking device of claim 1, wherein the heating plate is formed by splicing the plurality of heating units.

7. The photoresist pre-baking device of claim 1, wherein the heating plate further comprises a base substrate, and the plurality of heating units are formed on the base substrate.

8. A photoresist pre-baking method of using the photoresist pre-baking device of claim 1, comprising:
adjusting the heating parameter of each of the heating units of the heating plate by using the temperature controller, the heating parameter comprising at least one of a heating temperature and a heating duration; and
heating the substrate to be baked by using each of the heating units of the heating plate.

9. The method of claim 8, wherein after the step of heating the substrate to be baked by using each of the heating units of the heating plate, the method further comprises:
detecting a thickness of a photoresist in each baking region of the substrate to be baked after a lithographic process, and
the step of adjusting the heating parameter of each of the heating units of the heating plate by using the temperature controller comprises:
adjusting the heating parameter of each of the heating units of the heating plate according to the thickness of the photoresist in each baking region.

10. The method of claim 9, wherein after the step of detecting the thickness of the photoresist in each baking region of the substrate to be baked after the lithographic process, the method further comprises:
determining a target heating parameter of each baking region according to the thickness of the photoresist in each baking region,
the step of adjusting the heating parameter of each of the heating units of the heating plate by using the temperature controller comprises:
adjusting the heating parameter of each of the heating units of the heating plate according to the target heating parameter of each baking region.

11. The method of claim 10, wherein each of the heating units is configured to heat a respective baking region of the substrate to be baked, and the step of adjusting the heating parameter of each of the heating units of the heating plate according to the target heating parameter of each baking region comprises setting the heating parameter of each of the heating units as the target heating parameter of a baking region corresponding to each of the heating units.

12. The method of claim 8, wherein
the baking region of the substrate to be baked comprises a display region, a first driving region around the display region for disposing a source driving circuit and a second driving region around the display region for disposing a gate driving circuit,
the step of adjusting the heating parameter of each of the heating units of the heating plate by using the temperature controller comprises:
adjusting the heating parameter of each of the heating units of the heating plate, such that a heating temperature of a first heating unit is higher than a heating temperature of a second heating unit and/or a heating duration of the first heating unit is greater than a heating duration of the second heating unit,
wherein the first heating unit is a heating unit for heating the second driving region, and the second heating unit is a heating unit for heating the display region and the first driving region.

13. A lithographic apparatus, comprising the photoresist pre-baking device of claim 1.
